(19) United States
(12) Patent Application Publication
(10) Pub. No.: US 2024/0345178 A1
(43) Pub. Date: Oct. 17, 2024

(54) TRANSFORMER FAULT DETECTION

(71) Applicant: Rockwell Automation Technologies, Inc., Mayfield Heights, OH (US)

(72) Inventors: John Zhuo Liu, Shanghai (CN); Jasper Hao Yang, Shanghai (CN); Julie Haihui Lu, Shanghai (CN); Yujia Cui, Mequon, WI (US); Kadir Liano, Austin, TX (US); Tim Liu, Austin, TX (US); George Cheng, Cambridge (CA); Navid Zargari, Cambridge (CA); Bijan SayyarRodsari, Austin, TX (US); Jiangang Hu, Mequon, WI (US)

(21) Appl. No.: 18/299,655

(22) Filed: Apr. 12, 2023

(51) Int. Cl. G01R 31/52; G01R 31/08

(52) U.S. Cl. CPC G01R 31/52; G01R 31/088

(57) ABSTRACT

For transformer fault detection, a method generates a transition region that separates a health region and a fault region in a two-dimensional feature space of two feature indicators for a plurality of operation conditions using a fault detection model for a power transformer type. The method determines the feature indicators of a given power transformer of the power transformer type. The method determines whether the feature indicators in the transition region satisfy a fault condition. The method predicts an inter-turn short fault for the given power transformer in response to satisfying the fault condition or the feature indicators being in the fault region.

### BACKGROUND INFORMATION

The subject matter disclosed herein relates to transformer fault detection.

### BRIEF DESCRIPTION

A method for transformer fault detection is disclosed. The method generates, by use of a processor, a transition region that separates a health region and a fault region in a two-dimensional feature space of two feature indicators for a plurality of operation conditions using a fault detection model for a power transformer type. The method further determines the feature indicators of a given power transformer of the power transformer type. The method determines whether the feature indicators in the transition region satisfy a fault condition. The method predicts an inter-turn short fault for the given power transformer in response to satisfying the fault condition or the feature indicators being in the fault region.

An apparatus for transformer fault detection is disclosed. The apparatus includes a processor executing code stored by a memory. The processor generates a transition region that separates a health region and a fault region in a two-dimensional feature space of two feature indicators for a plurality of operation conditions using a fault detection model for a power transformer type. The processor further determines the feature indicators of a given power transformer of the power transformer type. The processor determines whether the feature indicators in the transition region satisfy a fault condition. The processor predicts an inter-turn short fault for the given power transformer in response to satisfying the fault condition or the feature indicators being in the fault region.

A computer program product for transformer fault detection is also disclosed. The computer program product includes a non-transitory computer readable storage medium comprising code executable by a processor. The processor generates a transition region that separates a health region and a fault region in a two-dimensional feature space of two feature indicators for a plurality of operation conditions using a fault detection model for a power transformer type. The processor further determines the feature indicators of a given power transformer of the power transformer type. The processor determines whether the feature indicators in the transition region satisfy a fault condition. The processor predicts an inter-turn short fault for the given power transformer in response to satisfying the fault condition or the feature indicators being in the fault region.

### BRIEF DESCRIPTION OF THE DRAWINGS

In order that the advantages of the embodiments of the invention will be readily understood, a more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1A is a schematic block diagram of drive system according to an embodiment;

FIG. 1B is a schematic diagram of power transformer according to an embodiment;

FIG. 1C is a schematic block diagram of fault detector according to an embodiment;

FIG. 2A is a schematic block diagram of detector data according to an embodiment;

FIG. 2B is a schematic block diagram of training data according to an embodiment;

FIG. 3A is a drawing of a feature space according to an embodiment;

FIG. 3B is a drawing of a feature space according to an alternate embodiment;

FIG. 3C is a drawing of a feature space according to an alternate embodiment;

FIG. 3D is a drawing of a feature space according to an alternate embodiment;

FIG. 3E is a drawing of a feature space according to an alternate embodiment;

FIG. 3F is a drawing of a fault localization map according to an alternate embodiment;

FIG. 3G is a drawing of a fit plot according to an embodiment;

FIG. 3H is a drawing of a feature space according to an alternate embodiment;

FIG. 3I is a drawing of a feature space according to an alternate embodiment;

FIG. 3J is a drawing of a feature space according to an alternate embodiment;

FIG. 4 is a schematic block diagram of a computer according to an embodiment;

FIG. 5A is a schematic flow chart diagram of a boundary generation method according to an embodiment;

FIG. 5B is a schematic flow chart diagram of a fault detection method according to an embodiment;

FIG. 5C is a schematic flow chart diagram of a fault condition determination method according to an embodiment; and

FIG. 5D is a schematic flow chart diagram of a fault condition determination method according to an alternate embodiment.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. The term “and/or” indicates embodiments of one or more of the listed elements, with “A and/or B” indicating embodiments of element A alone, element B alone, or elements A and B taken together.

Furthermore, the described features, advantages, and characteristics of the embodiments may be combined in any suitable manner. One skilled in the relevant art will recognize that the embodiments may be practiced without one or more of the specific features or advantages of a particular embodiment. In other instances, additional features and advantages may be recognized in certain embodiments that may not be present in all embodiments.

These features and advantages of the embodiments will become more fully apparent from the following description and appended claims or may be learned by the practice of embodiments as set forth hereinafter. As will be appreciated by one skilled in the art, aspects of the present invention may be embodied as a system, method, and/or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the present invention may take the form of a computer program product embodied in one or more computer readable medium(s) having program code embodied thereon.

The computer readable medium may be a tangible, non-transitory computer readable storage medium storing the program code. The computer readable storage medium may be, for example, but not limited to, an electronic, magnetic, optical, electromagnetic, infrared, holographic, micromechanical, or semiconductor system, apparatus, or device, or any suitable combination of the foregoing.

More specific examples of the computer readable storage medium may include but are not limited to a portable computer diskette, a hard disk, a random access memory (RAM), a read-only memory (ROM), an erasable programmable read-only memory (EPROM or Flash memory), a portable compact disc read-only memory (CD-ROM), a digital versatile disc (DVD), an optical storage device, a magnetic storage device, a holographic storage medium, a micromechanical storage device, or any suitable combination of the foregoing. In the context of this document, a computer readable storage medium may be any tangible medium that can contain, and/or store program code for use by and/or in connection with an instruction execution system, apparatus, or device.

Program code for carrying out operations for aspects of the present invention may be written in any combination of one or more programming languages, including an object-oriented programming language such as Python, Ruby, R, Java, Java Script, Smalltalk, C++, C sharp, Lisp, Clojure, PHP or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). The computer program product may be shared, simultaneously serving multiple customers in a flexible, automated fashion.

The schematic flowchart diagrams and/or schematic block diagrams in the Figures illustrate the architecture, functionality, and operation of possible implementations. It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Although various arrow types and line types may be employed in the flowchart and/or block diagrams, they are understood not to limit the scope of the corresponding embodiments. Indeed, some arrows or other connectors may be used to indicate only an exemplary logical flow of the depicted embodiment.

The description of elements in each figure may refer to elements of proceeding figures. Like numbers refer to like elements in all figures, including alternate embodiments of like elements.

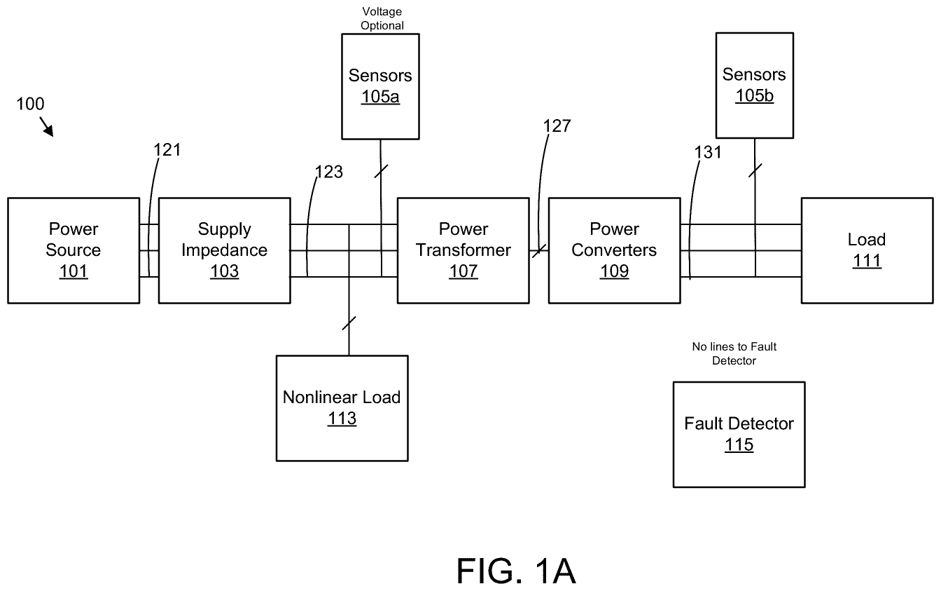

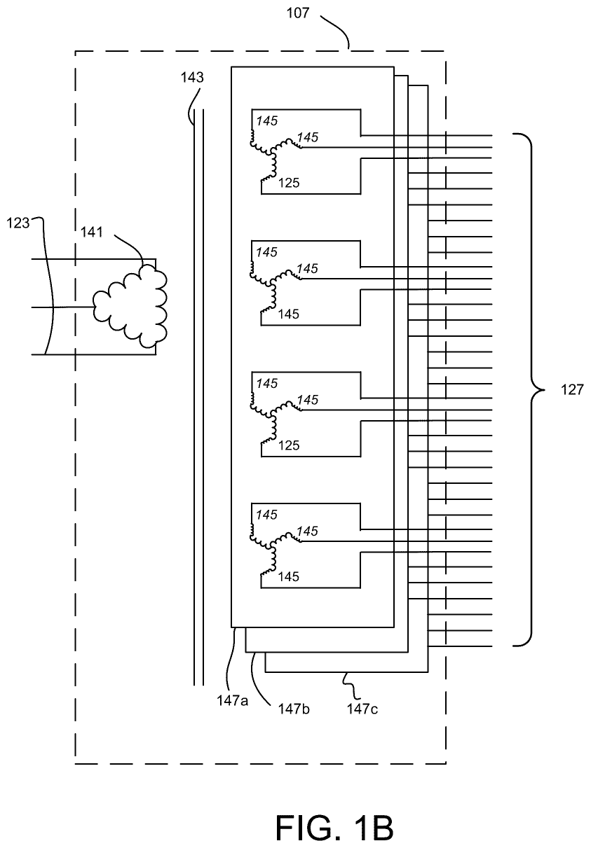

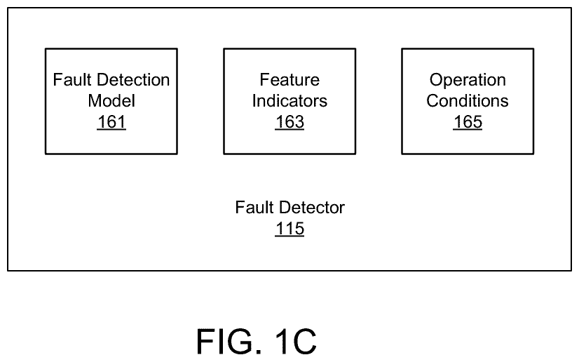

FIG. 1A is a schematic block diagram of one embodiment of a drive system 100. The drive system 100 may supply electrical power to a load 111 such as a motor load 111. The load 111 may be a salient motor, a non-salient motor, and the like. The electrical power originates at a power source 101. The power source 101 may supply three-phase power 121. In a certain embodiment, the power source 101 is three-phase grid power. The power source 101 may have a supply impedance 103. A power transformer 107 receives input power 123 from the power source 101.

In one embodiment, a nonlinear load 113 is coupled with the input power 123. First sensors 105a may measure the input power 123. The first sensors 105a may measure a primary phase current. In one embodiment, the first sensors 105a measure a primary phase voltage.

The power transformer 107 is coupled to the input power 123. The power transformer 107 may convert the input power 123 to a drive power 127 that is coupled to power converters 109. In one embodiment, the power converters 109 includes a rectifier, an inverter, and a controller. The rectifier may provide direct current (DC) power to the inverter. The controller may control the inverter to supply load power 131 to the load 111. The load power 131 may be modulated by the inverter to drive a motor load 111.

The power converters 109 may control the load 111 by supplying the load power 131 to the load 111. For example, the power converters 109 may control a motor load 111 to generate a specified torque at a specified angular velocity. In one embodiment, second sensors 105b measure a load current and/or load voltage of the load power 131.

The power transformer 107 may develop a fault such as an inter-turn short-circuit (ITSC). The fault may cause a catastrophic failure of the drive system 100, resulting in an unexpected system shutdown and/or extended repair and maintenance. As a result, early detection of faults in the power transformer 107 may enhance the life-cycle reliability of the drive system 100.

The embodiments predict and/or determine faults and/or potential faults. As a result, the faults may be mitigated in a timely manner, improving the operational availability and life-cycle reliability of the drive system 100. A fault detector 115 may detect the fault as will be described hereafter. The fault detector 115 may be embodied in the drive system 100. Alternatively, the fault detector 115 may be externally coupled to the drive system 100.

FIG. 1B is a schematic diagram of one embodiment of power transformer 107. In the depicted embodiment, the power transformer 107 includes a primary winding 141, a core 143, and a plurality of secondary windings 145. At least one secondary winding 145 may be organized in a section 147. The primary winding 141 may be a Delta winding or a Y winding. The secondary winding 145 may be a Delta winding or a Y winding. The primary winding 141 receives the input power 123 and provides the drive power 127.

FIG. 1C is a schematic block diagram of one embodiment of the fault detector 115. In the depicted embodiment, the fault detector 115 comprises a fault detection model 161, feature indicators 163, and operation conditions 165. The fault detection module 161, feature indicators 163, and operation conditions 165 may be organized as hardware, software, or combinations thereof.

In one embodiment, feature indicators 163 are measured and/or calculated. The feature indicators 163 may be measured and/or calculated for specified operation conditions 165. The operation conditions 165 comprise at least one of an ITSC, the primary phase voltage, the primary phase current, the supply impedance 103, a motor speed, a motor load, and the nonlinear load 113.

Table 1 lists some feature indicators 163, although other parameters may be employed as feature indicators 163.

TABLE 1
Current phase shift of primary side currents
The real and imaginary components of the negative
sequence of primary phase currents
A phase angle and a magnitude difference between
the D and Q currents of a Park's vector
transform of primary phase currents
Alpha-beta transforms of a phase voltage
Alpha-beta transforms of a phase current
The real and imaginary components of the
phasor difference or other combinations
between α and β admittance of an alpha-beta
transformation of primary phase admittance
Average power loss and average motor power

In one embodiment, a pair of two feature indicators 163 may form a feature point in the feature space. The location of the feature indicators 163 in the feature space may be used to predict a fault as will be described hereafter. The feature indicators 163 may be selected to separate fault conditions from normal operations for the power transformer 107 as will be described hereafter.

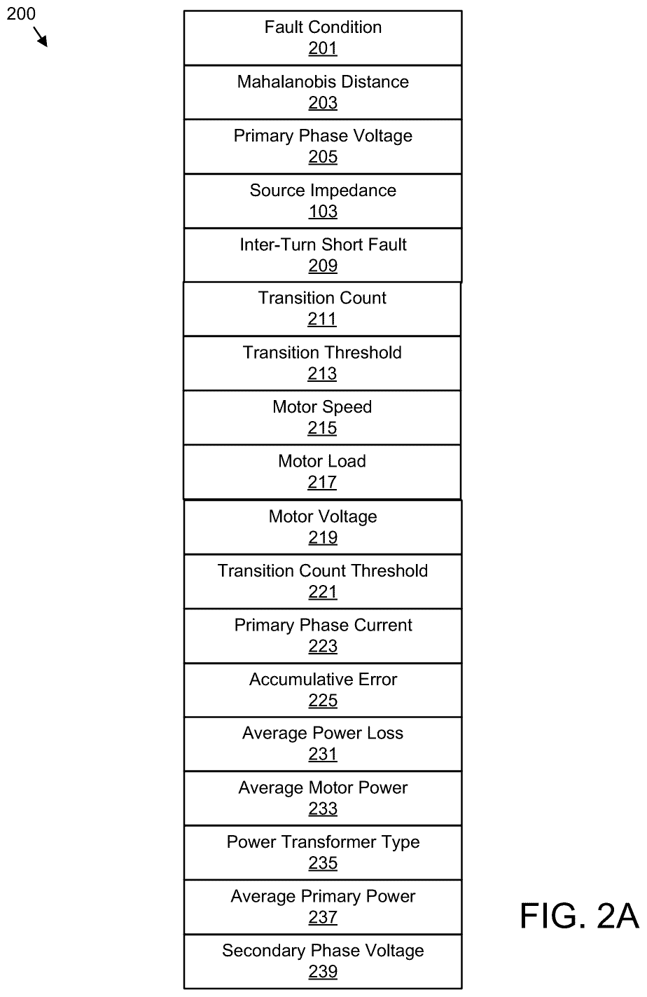

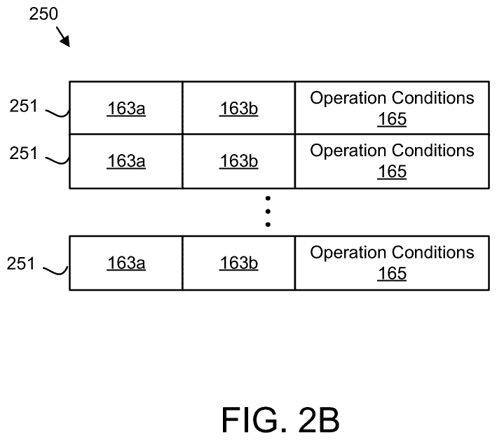

FIG. 2A is a schematic block diagram of detector data 200. The detector data 200 may be used to detect faults in the power transformer 107. The detector data 200 may be organized as a data structure in a memory. In the depicted embodiment, the detector data 200 includes a fault condition 201, a Mahalanobis distance 203, the primary phase voltage 205, the supply impedance 103, an ITSC 209, a transition count 211, an accumulated error 213, a motor speed 215, a motor load 217, a motor voltage 219, a transition count threshold 221, a primary phase current 223, and accumulative errors 225, an average power loss 231, an average motor power 233, the power transformer type 235, an average primary power 237, and a secondary phase voltage 239.

The fault condition 201 may specify conditions for predicting a fault such as an ITSC 209. The detection of the fault condition 201 will be described hereafter. The Mahalanobis distance 203 is a normalized distance between a feature point and the center of a Gaussian distribution of feature points in a feature space. The determination of the Mahalanobis distance 203 will be described hereafter.

The primary phase voltage 205 specifies the phase voltage of the three-phase power 121. The secondary phase voltage 239 specifies the phase voltage of the drive power 127. The primary phase current 223 specifies the phase current of the three-phase power 121. The supply impedance 103 specifies the impedance of the power source 101.

The ITSC 209 specifies a fault in the power transformer 107. The ITSC 209 may specify a fault phase of the fault, a fault severity of a fault, or combinations thereof. The transition count 211, accumulated error 213, transition count threshold 221, and accumulative error 225 may be used to detect the fault condition 201 and/or ITSC 209 as will be described hereafter.

The motor speed 215, motor load 217, motor voltage 219, average power loss 231, average primary power 237, and/or average motor power 233 may be measured and/or calculated for a motor load 111. The average power loss 231 and average motor power 233 may be calculated from voltage and current measurements at the sensors 105. The power transformer type 235 may specify a rating for the power transformer 107. In addition, the power transformer type 235 may specify a range of power transformer parameters.

FIG. 2B is a schematic block diagram of one embodiment of training data 250. The fault detection model 161 may be generated from the training data 250. The training data 250 may be organized as a data structure in a memory. In the depicted embodiment, the training data 250 includes a plurality of training data entries 251. Each training data entry 251 may include two feature indicators 163a-b. The two feature indicators 163a-b specify a feature point in a feature space. The two feature indicators 163a-b may specify a feature point in a feature space for the corresponding operation conditions 165.

In one embodiment, each training data entry 251 represents feature indicators 163ab-b and/or operation conditions 165 for a healthy power transformer 107. In an alternate embodiment, each training data entry 251 represents feature indicators 163a-b and/or operation conditions 165 for a faulty power transformer 107. In a certain embodiment, each training data entry 251 represents feature indicators 163a-b and/or operation conditions 165 for either a healthy power transformer 107 or a faulty power transformer 107 and are labeled as such.

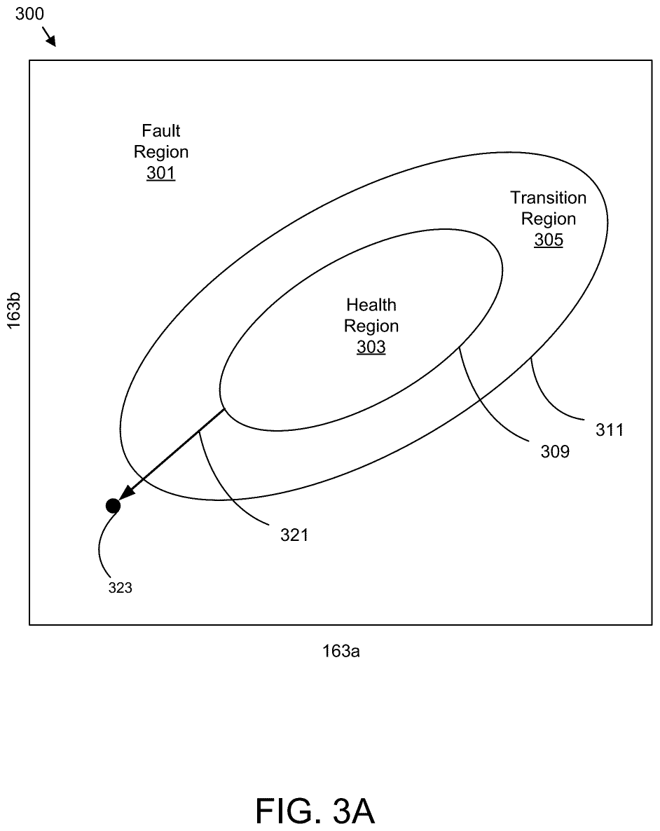

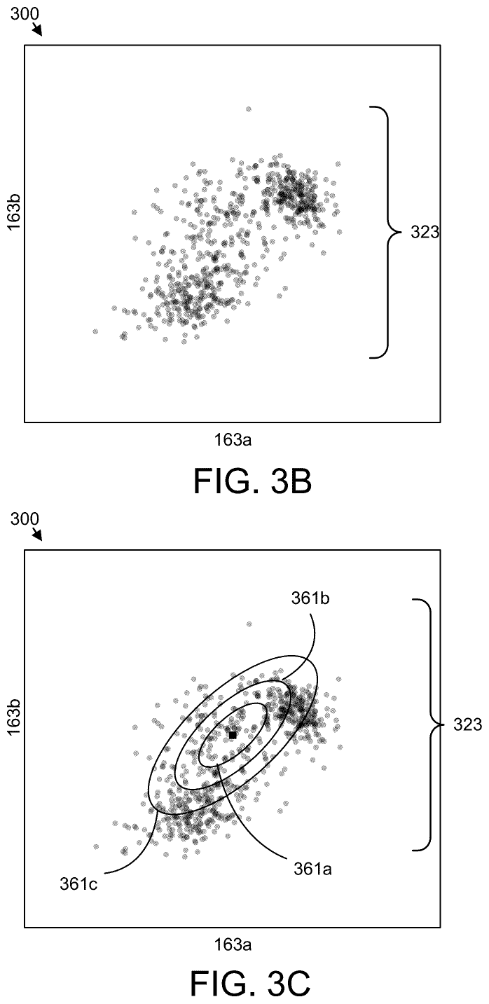

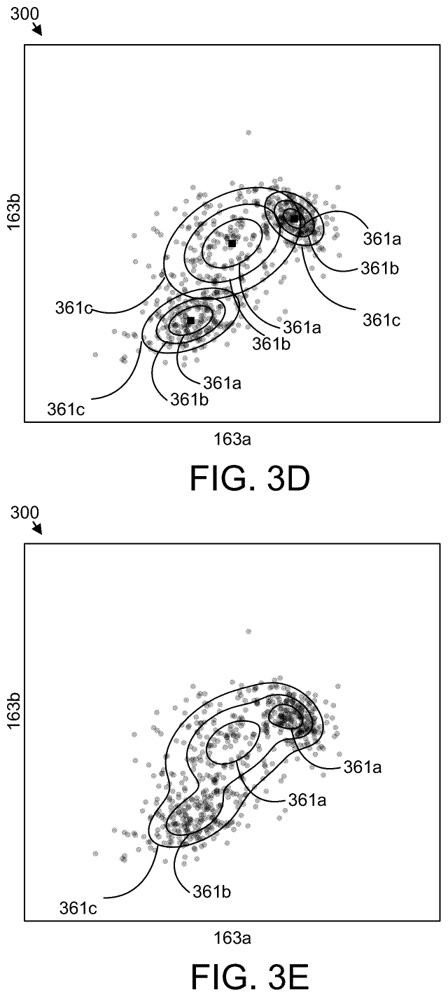

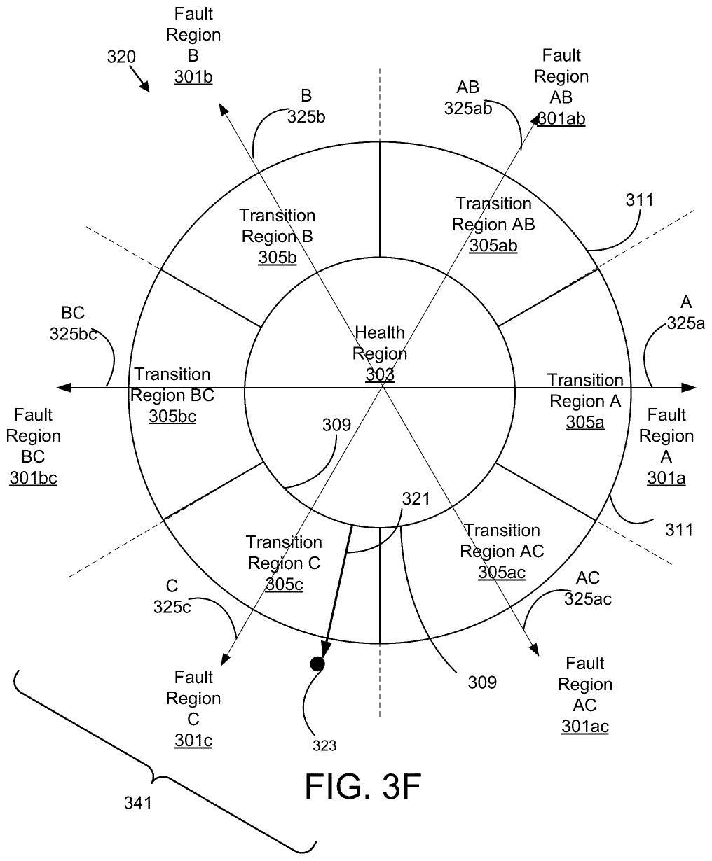

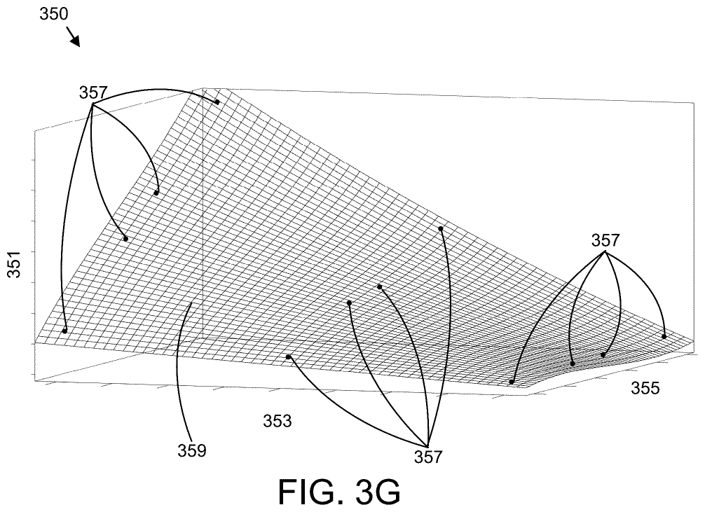

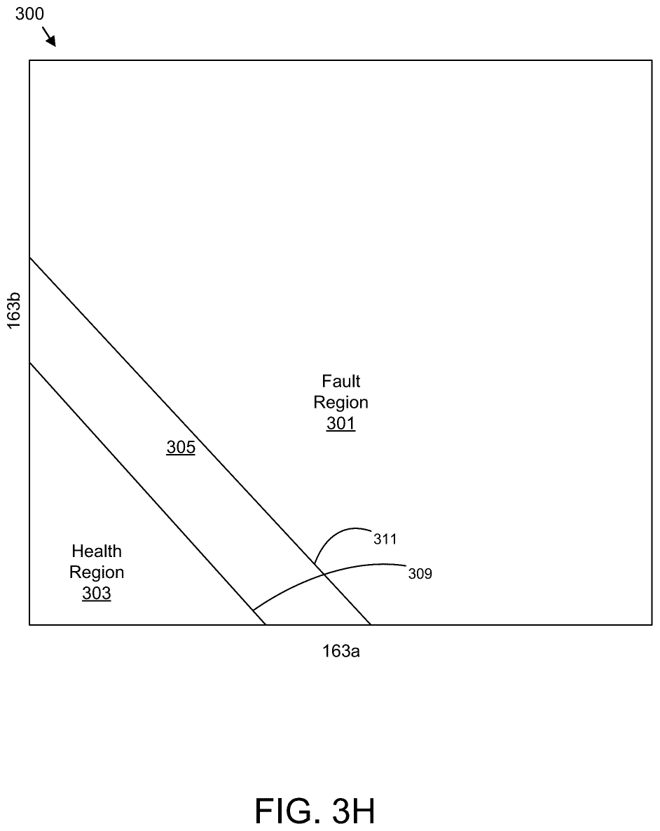

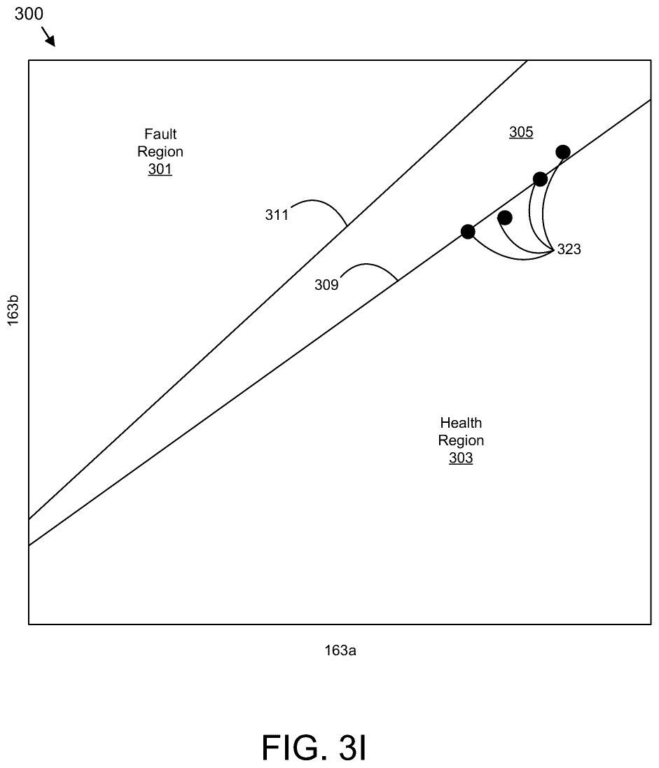

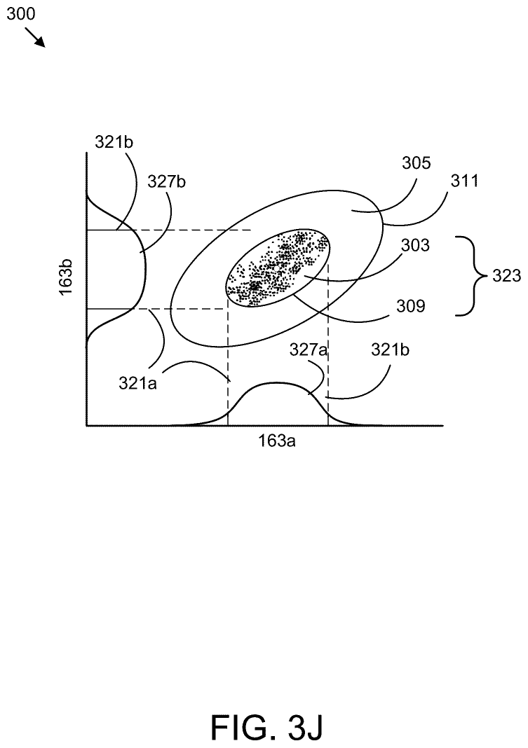

FIG. 3A is a drawing of one embodiment of a feature space 300. In the depicted embodiment, the feature space 300 is a two-dimensional space formed from a plurality of values for a first feature indicator 163a and a second feature indicator 163b.

Within the feature space 300, a health region 303 is determined. In one embodiment, the health region 303 is calculated from the training data 250. In addition, the health region 303 may be bounded by a health threshold 309. When testing a power transformer 107 to predict a fault condition 201 and/or ITSC 209, feature indicators 163a-b that fall in the health region 303 may not predict a potential fault and/or fault condition 201.

A fault region 301 is also determined within the feature space 300. The fault region 301 may be bounded by a fault threshold 311. When testing the power transformer 107 to predict a fault condition 201 and/or ITSC 209, feature indicators 163a-b such as a feature point 323 that fall within the fault region 301 may predict a potential fault.

In one embodiment, the health threshold 309 is not equivalent to the fault threshold 311. Values of feature indicators 163a-b between the health threshold 309 and the fault threshold 311 may form a transition region 305. Feature indicators 163a-b that fall within the transition region 305 may optionally predict a potential fault as will be described hereafter.

The feature space 300 may be used to detect faults such as fault conditions 201 and/or ITSC 209. The sensors 105 may measure operating parameters of the drive system 100 and/or power transformer 107. The fault detector 115 may determine feature indicators 163 based on the measurements. The feature indicators 163 may be virtually represented as a feature point 323 in the feature space 300. The fault detector 115 may predict the fault conditions 201 and/or ITSC 209 based on the position of the feature point 323 in the feature space 300. In the depicted embodiment, the position of the feature point 323 in the fault region 301 indicates that an ITSC 209 is likely.

In one embodiment, a fault severity 321 is determined as a distance such as a Mahalanobis distance 203 from the health threshold 309 to at least one feature point 323. The fault severity 321 may predict the severity of a fault such as an ITSC 209.

In one embodiment, the feature indicators 163a-b are a current phase shift of primary phase currents 223. In addition, the feature space 300 may represent a time domain. The equations 1-3 may calculate current phase shifts Δφ_{ab}, Δφ_{bc}, and Δφ_{ca} for phase currents φ_{In} using Equations 1-3.

$${Δφ}_{ab} = {φ}_{Ia} - {φ}_{Ib} \qquad ( 1 )$$

$${Δφ}_{bc} = {φ}_{Ib} - {φ}_{Ic} \qquad ( 2 )$$

$${Δφ}_{ca} = {φ}_{Ic} - {φ}_{Ia} \qquad ( 3 )$$

In addition, principal component analysis may extract the current phase shift feature indicators Δφ₁ and Δφ₂ 163a-b from Δφ_{ab}, Δφ_{bc}, and Δφ_{ca}.

In one embodiment, the feature indicators 163a-b are the real and imaginary components of the negative sequence of primary phase currents I 223 as shown in Equation 4 for the negative sequence of Equation 5.

$$\{ \begin{matrix}Real ( {I}_{-} ) \text{=>} first feature indicator 163 a \\ Imag ( {I}_{-} ) \text{=>} second feature indicator 163 b\end{matrix} \qquad ( 4 )$$

$${I}_{-} = \frac{1}{3} ( {I}_{a} + {a}^{2} {I}_{b} + {aI}_{c} ) , a = 1 ∠120° , {a}^{2} = 1 ∠240° \qquad ( 5 )$$

In one embodiment, the feature indicators 163a-b are a phase angle and a magnitude difference between D and Q currents of a Park's vector transform of the primary phase currents I 223 as shown in Equation 6.

$$\{ \begin{matrix}∠ {I}_{D} - ∠ {I}_{Q} \text{=>} first feature indicator 163 a \\ \vert {I}_{D} \vert - \vert {I}_{Q} \vert \text{=>} second feature indicator 163 b\end{matrix} \qquad ( 6 )$$

In one embodiment, the feature indicators 163a-b are an alpha-beta (αβγ) transform g of the phase voltage 205 and the primary phase current 223 for the power transformer type 235. The first feature indicator Δgₓ 163a may be expressed as shown in Equation 7 and the second feature indicator Δg_{y} 163b as shown in Equation 8, where ω=2π*frequency and j is an imaginary number.

$$Δ {g}_{x} = Real ( {g}_{α} ( j ω ) - {g}_{β} ( j ω ) ) \qquad ( 7 )$$

$$Δ {g}_{y} = Imag ( {g}_{α} ( j ω ) - {g}_{β} ( j ω ) ) \qquad ( 8 )$$

In one embodiment, the feature indicators 163a-b are αβγ transforms g of the phase voltage 205 and the primary phase current 223 for the power transformer type 235. The first feature indicator Δgₓ 163a may be expressed as shown in Equation 9 and the second feature indicator Δg_{y} 163b as shown in Equation 10.

$$Δ {g}_{x} = ( ∠ {g}_{α} ( j ω ) - ∠ {g}_{β} ( j ω ) ) \qquad ( 9 )$$

$$Δ {g}_{y} = ( \vert {g}_{α} ( j ω ) \vert - \vert {g}_{β} ( j ω ) \vert ) \qquad ( 10 )$$

In one embodiment, the feature indicators 163a-b are αβγ transforms g of the phase voltage 205 and the primary phase current 223 for the power transformer type 235. The first feature indicator Δgₓ 163a may be expressed as shown in Equation 11 and the second feature indicator Δg_{y} 163b as shown in Equation 12.

$$Δ {g}_{x} = Imag ( {g}_{α} ( j ω ) - {g}_{β} ( j ω ) ) \qquad ( 11 )$$

$$Δ {g}_{y} = ( \vert {g}_{α} ( j ω ) \vert - \vert {g}_{β} ( j ω ) \vert ) \qquad ( 12 )$$

In one embodiment, the feature indicators 163a-b are the real and imaginary components of the phasor difference between α and β admittance of an alpha-beta transformation of primary phase admittance as shown in Equation 13.

$$\{ \begin{matrix}Real ( {Y}_{α} ( s ) - {Y}_{β} ( s ) ) \text{=>} first feature indicator 163 a \\ Imag ( {Y}_{α} ( s ) - {Y}_{β} ( s ) ) \text{=>} second feature indicator 163 b\end{matrix} \qquad ( 13 )$$

FIG. 3B is a drawing of one embodiment of a feature space 300. In the depicted embodiment, a plurality of feature points 323 for a plurality of pairs of feature indicators 163a-b are shown. In the depicted embodiment, the pairs of feature indicators 163a-b are from healthy power transformers 107. In one embodiment, the feature indicators 163a-b are measured from known healthy power transformers 107. In addition, the feature indicators 163a-b may be measured from a plurality of power transformers 107 that are installed in the field and that have no known issues or failures.

FIG. 3C is a drawing of one embodiment of a feature space 300. The feature points 323 of FIG. 3B are shown. In the depicted embodiment, probability distributions 361a-c are shown for the distribution D of feature points 323. The probability distributions 361a-c may represent same probabilities of health for the power transformer 107. The probability distributions 361a-c may be concentric regions based on one or more Mahalanobis distances 203 from the distribution D of same probabilities of health such as 0.9, or inverse probabilities of failure such as 0.1.

FIG. 3D is a drawing of one embodiment of feature space 300. In the depicted embodiment, three analytical distributions D of the feature points 323 are calculated. Each distribution D may have at least one probability distributions 361a-c.

In one embodiment, each point on a probability distribution 361a-c presents equivalent probabilities of healthy and/or an inverse probability of developing a fault. In one embodiment, each point on the probability distributions 361a-c are a specified Mahalanobis distance 203 from the local distribution D of feature points 323.

FIG. 3E is a drawing of one embodiment of the feature space 300. In the depicted embodiment, the probability distributions 361a-c of FIG. 3D are merged to form merged unified mixed probability distributions 361a-c. In one embodiment, the points on the merged probability distributions 361a-c have equivalent probabilities of health or developing a fault.

FIG. 3F is a drawing of one embodiment of a normalized fault localization map 320. In the depicted embodiment, the health region 303, transition region 305, and fault region 301 are divided into sectors indicating the location of faults on the primary windings 141 of the power transformer 107. In the depicted embodiments, the sectors A, B, and C indicate a single fault located in the corresponding phase windings. The sectors AB, BC, and AC indicate two faults located in two different phase windings (A,B), (B,C), and (A,C) respectively. The location of a fault may be determined by which sector a feature point 323 falls in the fault localization map 320.

In the depicted embodiment, two feature indicators 163 are determined from the detector data 200 and represented as a feature point 323. The region where the feature point 323 is positioned indicates the fault location 341 of the system 100. In the depicted embodiment, the feature point 323 is in the fault region 301c, indicating a fault in phase C of the power transformer 107. In one embodiment, the fault severity 321 is determined from a distance such as a Mahalanobis distance 203 from the health threshold 309 to the feature point 323.

FIG. 3G is a drawing of one embodiment of a fit plot 350. The fit plot 350 graphs a D intercept 351 for a plurality of transformer faults 357 such as ITSC 209 that were determined at specified percent loads 353 and motor frequencies 355 for the load 111. A regression-based threshold intercept surface 359 is fit to the transformer faults 357. In one embodiment, a three-dimensional lookup table model representing the regression-based threshold intercept surface 359 is generated by regressing intercept values from the transformer faults 357. The three-dimensional lookup table model may be fit to the transformer faults 357 with a polynomial. The regression-based threshold intercept surface 359 may represent a three-dimensional health threshold 309.

FIG. 3H is a drawing of one embodiment of the feature space 300. In the depicted embodiment, the feature indicators 163 are an alpha voltage V_{α} and a beta voltage V_{β} of the primary phase voltage Vₚᵣᵢ 205 and the secondary voltage V_{sec} 239 as translated into an alpha-beta (αβ) frame as shown in Equation 14 or as a number Nₚᵣᵢ of primary windings 141 and a number N_{sec} secondary windings 145 translated into the αβ frame as shown in Equation 15.

$${k}_{α , β} = \frac{\vert {V}_{pri \_α , β} \vert}{\vert {V}_{sec \_α , β} \vert} \qquad ( 14 )$$

$${k}_{α , β} = \frac{{N}_{pri \_α , β}}{{N}_{sec \_α , β}} \qquad ( 15 )$$

The fault model 161 may generate the health region 303, transition region 305, and fault region 301 as half planes bounded by sloped lines of the health threshold 309 and the fault threshold 311. In one embodiment, the health threshold 309 and/or the fault threshold 311 are each determined for a specified value of the D intercept 351 of FIG. 3G. In one embodiment, the health threshold 309 has a slope of −1 in the feature space 300 for intercepts that satisfy Equations 16 and 17.

$${k}_{β} <= {y}_{α} \qquad ( 16 )$$

$${k}_{α} <= {x}_{α} \qquad ( 17 )$$

In addition, the fault threshold 311 may have a slope of −1 in the feature space 300 for intercepts that satisfy Equations 18 and 19.

$${k}_{β} > {y}_{α} \qquad ( 18 )$$

$${k}_{α} > {x}_{α} \qquad ( 19 )$$

The fault detection model 161 may be based on the health threshold 309 and the fault thresholds 311. In one embodiment, the fault detection model 161 generates the health region 303, the transition region 305, and/or fault region 301 from the health threshold 309 and/or fault threshold 311.

FIG. 3I is a drawing of one embodiment of the feature space 300. The fault detection model 161 may be based on the average power loss dP 231 feature indicator 163b calculated using Equation 20 and the average motor power Pmot 233 feature indicator 163a where Ppri is the average primary power 237.

$$dP = Ppri - Pmot \qquad ( 20 )$$

The fault detection model 161 may be trained offline using the average power loss 231 and average motor power 233 feature indicators 163 calculated from data for various healthy operating conditions 165 to generate the sloped lines in feature space 300. In one embodiment, the fault detection model 161 is trained using supervised learning.

In one embodiment, during runtime monitoring of the power transformer 107, the trained fault detection model 161 is used to create the health region 303, the transition region 305, and/or fault region 301 in the indicator space 300 for the current operating condition 165.

In the depicted embodiment, the health threshold 309 of the health region 303 is a linear regression of healthy cases represented by healthy feature points 323 of healthy feature indicators 163. The fault detection model 161 generates fault threshold 309 and transition region 305 as the sloped lines calculated from the health threshold 309 and/or a user specified tolerance.

FIG. 3J is a drawing of one alternate embodiment of the feature space 300. In the depicted embodiment, the health threshold 309 is determined as a specified standard deviation 321 of a 2-dimensional multivariate gaussian distribution 327 for the feature points 323 defined by the feature indicators 163. In addition, the fault threshold 311 may be defined by another specified standard deviation (not shown) of the 2-dimensional multivariate gaussian distribution 323.

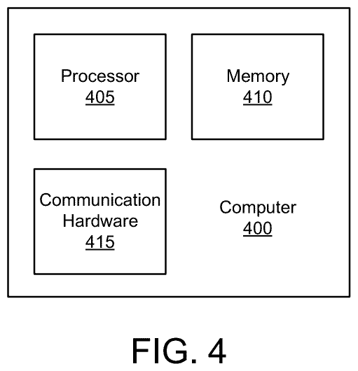

FIG. 4 is a schematic block diagram of a computer 400. The computer 400 may be embodied in the fault detector 115. Alternatively, the computer 400 may be embedded in an external test device. In the depicted embodiment, the computer 400 includes a processor 405, memory 410, and communication hardware 415. The memory 410 may store code and data. The processor 405 may execute the code and process the data. The communication hardware 415 may communicate with other devices.

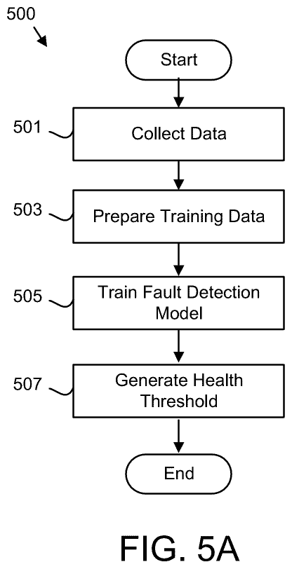

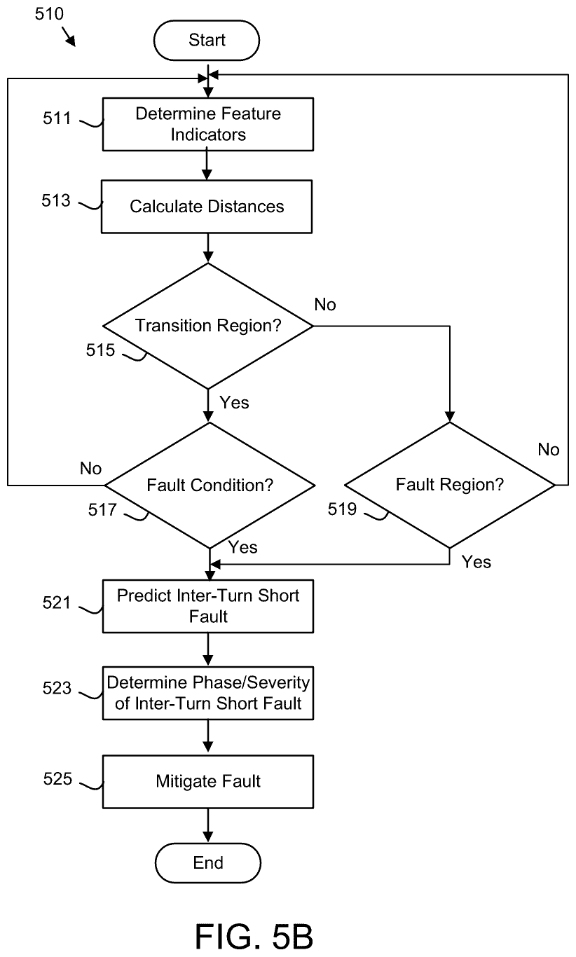

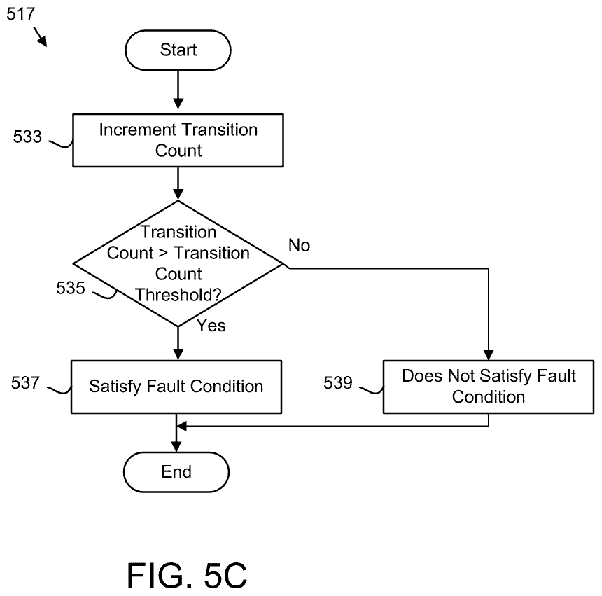

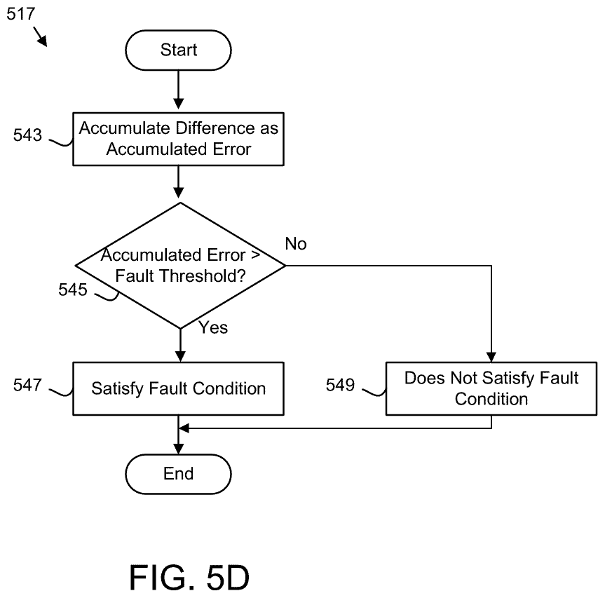

FIG. 5A is a schematic flow chart diagram of a boundary generation method 500. The method 500 may train and/or generate the fault detection model 161. In addition, the method 500 may generate the health threshold 309 and/or fault threshold 311. The method 500 may be performed by the computer 400 and/or the processor 405.

The method 500 starts, and in one embodiment, the sensors 105 collect 501 data. The collected data may include but is not limited to the detector data 200. In addition, the processor 405 may calculate elements of the detector data 200 from the collected data.

The processor 405 may prepare 503 the training data 250. In one embodiment, all training data entries 251 are from healthy drive systems 100 and/or power transformers 107. In a certain embodiment, two feature indicators 163 are selected for the training data 250. The feature indicators 163 may be selected based on the power transformer type 235. Alternatively, the feature indicators 163 may be selected based on the available detector data 200.

The processor 405 may train 505 the fault detection model 161. In one embodiment, the fault detection model 161 is trained 505 by determining a feature point 323 for the feature indicators 163. The processor 405 may determine a distribution D for the feature points 323. The fault detection model 161 may use the distribution to predict faults.

In a certain embodiment, the feature indicators 163 are binned based on the operating conditions 165. For example, the operating conditions 165 may be organized as n bins. A separate fault detection model 161 may be trained 505 for each of the n bins of operating conditions 165. As a result, the processor 405 may determine distributions D 323 corresponding to each of the n bins of operating conditions 165. One or more fault detection models 161 may be selected based on the current operating conditions 165 and used to predict a fault for the drive system 100 and/or power transformer 107.

The processor 405 may apply a learning algorithm to the training data 250 to generate the fault detection model 161. The learning algorithm may be a linear regression, a logistic regression, a naïve Bayes classifier, a nearest known neighbor algorithm, K-means clustering, random forest, a decision tree, a classification and regression tree, and the like. The fault detection model 161 may be used to predict a fault for the drive system 100 and/or power transformer 107.

In one embodiment, the fault detection model 161 is trained 505 off-line. For example, the fault detection model 161 may be trained 505 on training data 250 collected from a plurality of drive systems 100 and/or power transformers 107. The power transformers 107 may each be of the same power transformer type 235. Alternatively, the fault detection model 161 may be trained 505 on training data 250 collected from a single drive system 100 and/or power transformer 107. The training data 250 may be collected during the operation and/or testing of the drive system 100.

The processor 405 may generate 507 the health threshold 309 and/or fault threshold 311 using the fault detection model 161. The health threshold 309 and/or fault threshold 311 may each be specified by a Mahalanobis distance 203. The health threshold 309 may comprise points that are first Mahalanobis distance 203 from the distribution D and the fault threshold 311 may comprise points that are second Mahalanobis distance 203 from the distribution D.

The fault detector 115 and/or processor 405 may generate 507 the transition region 305 that separates the health region 303 and the fault region 301 in the two-dimensional feature space 300 of two feature indicators 163 for a plurality of operation conditions 165 using the fault detection model 161 for a power transformer type 235 and the method 500 ends. The health threshold 309 and/or fault threshold 311 may be used to define the health region 303, transition region 305, and/or fault region 301. In addition, the fault threshold 311, transition region 305, and/or fault region 301 may be used to predict faults for the drive system 100 and/or power F transformer 107.

Figure SB is a schematic flow chart diagram of one embodiment of a fault detection method 510. The method 510 may determine and/or predict the ITSC 209 in the drive system 100 and/or power transformer 107. The method 510 may be performed by the fault detector 115.

The method 510 starts, and in one embodiment, the fault detector 115 determines 511 the feature indicators 163. The fault detector 115 may employ the sensors 105 to measure the feature indicators 163 and/or feature indicator precursors. The feature indicators 163 and/or feature indicator precursors may be measured in real time. In addition, the fault detector 115 may calculate one or more feature indicators 163 from the feature indicator precursors. The fault detector 115 may determine 511 the feature indicators 163 of a given power transformer 107 based on the power transformer type 235.

The fault detector 115 may calculate 513 distances to the feature indicators 163 and/or corresponding feature points 323. The distances may be calculated 513 from the health threshold 309 and/or fault threshold 311. In addition, the feature indicators 163 and/or feature points 323 may be identified as being in one of the health region 303, the transition region 305, or fault region 301.

Based on the Mahalanobis distances 203 of the feature indicators 163 and/or corresponding feature points 323 from the health threshold 309, the fault detector 115 may determine 515 if the feature indicators 163 and/or feature points 323 are in the transition region 305. If the feature indicators 163 are not in the transition region 305, the fault detector 115 determines 519 whether the feature indicators 163 and/or feature points 323 are in the fault region 301. If the feature indicators 163 and/or feature points 323 are not in the fault region 301, the fault detector 115 loops to continue determining 511 the feature indicators 163 and/or feature points 323.

If the feature indicators 163 are in the transition region 305, the fault detector 115 determines if the fault condition 201 is satisfied. The determination of whether the fault condition 201 is satisfied is described in more detail in FIGS. 5C and 5D. If the fault condition 201 is not satisfied, the fault detector 115 loops to determine 511 the feature indicators 163.

If the fault detector 115 determines 517 that the fault condition 201 is satisfied or if the fault detector 115 determines 519 that the fault indicators 163 are in the fault region 301, the fault detector 115 predicts and/or determines 521 there is an ITSC 209. The ITSC 209 may be predicted and/or determined 521 in real time. In addition, the fault detector 115 may determine 523 the fault location 341 and/or fault severity 321 of the ITSC 209 as described in FIGS. 3A and 3F. The ITSC 209 may be predicted and/or determined 521 for a given power transformer 107 of a power transformer type 235.

The fault detector 115 may mitigate 525 the ITSC 209 and the method 510 ends. The ITSC 209 may be mitigated 525 by issuing a warning such as a warning to an administrator. In addition, the fault detector 115 may mitigate 525 the ITSC 209 by turning off the drive system 100 and/or power transformer 107. In one embodiment, the ITSC 209 is mitigated 525 by directing the replacement of the power transformer 107. In a certain embodiment, the replacement power transformer 107 is automatically ordered.

FIG. 5C is a schematic flow chart diagram of one embodiment of the fault condition determination method 517 of FIG. 5B. In the depicted embodiment, the transition count 211 is incremented in response to the feature indicators 163 being in the transition region 305. The transition count 211 may be initialized whenever the feature point 323 is in the health region 303. Alternatively, the transition count 211 may be re-initialized after a specified time interval.

The fault detector 115 determines 535 if the transition count 211 exceeds the transition count threshold 221. If the transition count 211 exceeds the transition count threshold 221, the feature indicators 163 satisfy 537 the fault condition 201. However, if the transition count does not exceed the transition count threshold 221, the feature indicators 163 do not satisfy the fault condition 201. The fault condition determination method 517 does not predict a fault if there are only occasional feature points 323 in the transition region 305 but does predict the fault if more feature points 323 are determined to be in the transition region 305.

FIG. 5D is a schematic flow chart diagram of one alternate embodiment of the fault condition determination method 517 of FIG. 5B. In the depicted embodiment, a difference such as a Mahalanobis distance 203 of the feature indicators 163 and/or feature points 323 in the transition region 205 and the health threshold 309 is accumulated 543 to the accumulative error 225. The accumulative error 225 may be initialized when a feature indicator 163 and/or feature point 323 is in the health region 303. Alternatively, the accumulative error 225 may be reinitialized after a specified time interval.

The fault detector 115 may determine 545 if the accumulative error 225 exceeds a difference of the fault threshold 311 and the health threshold 309. If the accumulative error 225 exceeds a difference of the fault threshold 311 and the health threshold 309, the fault condition 201 is satisfied 547 but if the accumulative error 225 does not exceed the difference, the fault condition 201 is not satisfied 549. The depicted fault condition determination method 517 predicts a fault if few consecutive feature indicators 163 and/or feature points 323 in the transition region 305 are near the fault threshold 311 or more consecutive feature indicators 163 and/or feature points 323 in the transition region 305 are near the health threshold 309.

### Problem/Solution

A power transformer 107 such as the power transformer 107 in a drive system 100 may develop a fault such as an ITSC 209. An unplanned failure of the power transformer 107 may result in the drive system 100 and related automation equipment being unavailable for use and expensive down time.

The embodiments predict the ITSC 209 from the fault indicators 163 using a fault detection model 161. The fault detection model 161 may be trained on training data 250 comprising fault indicators 163 and/or operating conditions 165 for power transformers 107 of a power transformer type 235. The fault detection model 161 predicts the ITSC 209 based on current measured or calculated fault indicators 163. The prediction of the ITSC 209 may be made in real time.

The embodiments may employ a transition region 305 to determine whether fault indicators 163 that are outside of the health region 303 predict an ITSC 209. The fault detector 161 may not predict an ITSC 209 in response to occasional feature indicators 163 outside of the health region 303. Thus, the embodiments minimize false positive predictions. As a result, ITSC 209 are efficiently and accurately predicted, improving the efficiency of the fault detector 115 and the drive system 100 and reducing down time for the drive system 100.

This description uses examples to disclose the invention and also to enable any person skilled in the art to practice the invention, including making and using any devices or systems and performing any incorporated methods. The patentable scope of the invention is defined by the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method comprising:
generating, by use of a processor, a transition region that separates a health region and a fault region in a two-dimensional feature space of two feature indicators for a plurality of operation conditions using a fault detection model for a power transformer type;
determining the feature indicators of a given power transformer of the power transformer type;
determining whether the feature indicators in the transition region satisfy a fault condition; and
predicting an inter-turn short fault for the given power transformer in response to satisfying the fault condition or the feature indicators being in the fault region.

2. The method of claim 1, the method further comprising determining a fault phase from a fault region of a fault localization map of the inter-turn short fault and/or a fault severity of the inter-turn short fault as a distance from a health region.

3. The method of claim 1, wherein the fault detection model is generated from training data comprising the feature indicators.

4. The method of claim 1, wherein the fault detection model generates the health region, the transition region, and the fault region as concentric regions based on a Mahalanobis distance from a distribution of healthy feature indicators.

5. The method of claim 4, wherein the feature indicators are a current phase shift of primary phase currents and the two-dimensional feature space is in a time domain.

6. The method of claim 4, wherein the feature indicators are a negative sequence of primary phase currents.

7. The method of claim 4, wherein the feature indicators are a phase angle and a magnitude difference between D and Q currents of a Park's vector transform of primary phase currents.

8. The method of claim 4, wherein the feature indicators are alpha-beta transforms of a primary phase voltage and a primary phase current for the power transformer type, the feature indicators expressed as Δgₓ=Real (g_{α}(jω)−g_{β}(jω)) and Δg_{y}=Imag (g_{α}(jω)−g_{β}(jω)) where ω=2π*frequency and j is an imaginary number.

9. The method of claim 4, wherein the feature indicators are alpha-beta transforms of a primary phase voltage and a primary phase current for the power transformer type, the feature indicators expressed as Δg_{y}=(|g_{α}(jω)|−|g_{β}(jω)|) and Δgₓ=∠g_{α}(jω)−∠g_{β}(jω)) where ω=2π*frequency and is an imaginary number.

10. The method of claim 4, wherein the feature indicators are alpha-beta transforms of a primary phase voltage and a primary phase current for the power transformer type, the feature indicators expressed as Δg_{y}=(|g_{α}(jω)|−|g_{β}(jω)|) and Δgₓ=Imag(g_{α}(jω)−g_{β}(jω)) where ω=2π*frequency and j is an imaginary number.

11. The method of claim 4, wherein the feature indicators are real and imaginary components of the phasor difference between α and β admittance of alpha-beta transformation of primary phase admittance.

12. The method of claim 4, wherein the fault condition is satisfied in response to a transition count of feature indicators in the transition region exceeding a transition count threshold.

13. The method of claim 4, wherein the fault condition is satisfied in response to the feature indicators in the transition region, accumulating a difference of a Mahalanobis distance of the feature indicators and the health threshold as an accumulative error, and determining that the accumulated error exceeds the difference of the fault threshold and the health threshold.

14. The method of claim 1, the fault detection model generates the health region, the transition region, and the fault region as half planes bounded by sloped lines defined from a distribution of healthy feature indicators.

15. The method of claim 14, wherein the fault detection model is calculated based on a specified D Intercept as the sloped lines generated from a three-dimensional plot of the D intercept, operational motor frequency, and percent load generated for variations of operating conditions.

16. The method of claim 15, wherein the fault detection model generates the transition region as the sloped lines based on primary phase voltage and secondary phase voltage feature indicators projected into a αβ frame.

17. The method of claim 14, wherein the feature indicators are average power loss and average motor power, and the health boundary of the health region is a linear regression of healthy feature indicators.

18. The method of claim 17, wherein the fault detection model is trained on the average power loss and the average motor power feature indicators and generates the transition region using the fault detection model as the sloped lines interpolated from healthy feature indicators that indicate healthy performance of the power transformer.

19. An apparatus comprising:
a processor executing code stored on a memory to perform:
generating a transition region that separates a health region and a fault region in a two-dimensional feature space of two feature indicators for a plurality of operation conditions using a fault detection model for a power transformer type;
determining the feature indicators of a given power transformer of the power transformer type;
determining whether the feature indicators in the transition region satisfy a fault condition; and
predicting an inter-turn short fault for the given power transformer in response to satisfying the fault condition or the feature indicators being in the fault region.

20. A computer program product comprising a non-transitory computer readable storage medium comprising code executable by a processor to perform:
generating a transition region that separates a health region and a fault region in a two-dimensional feature space of two feature indicators for a plurality of operation conditions using a fault detection model for a power transformer type;
determining the feature indicators of a given power transformer of the power transformer type;
determining whether the feature indicators in the transition region satisfy a fault condition; and
predicting an inter-turn short fault for the given power transformer in response to satisfying the fault condition or the feature indicators being in the fault region.
